(19) United States
(12) Patent Application Publication
(10) Pub. No.: US 2026/0282498 A1
(43) Pub. Date: Sep. 17, 2026

(54) MOSFET TRANSISTOR

(71) Applicants: STMicroelectronics (Rousset) SAS, Rousset (FR); STMicroelectronics (Crolles 2) SAS, Crolles (FR)

(72) Inventors: Franck JULIEN, La Penne sur Huveaune (FR); Julien DELALLEAU, Rousset (FR); Julien DURA, Rousset (FR); Julien AMOUROUX, Aix en Provence (FR); Stephane MONFRAY, Eybens (FR)

(73) Assignees: STMicroelectronics (Rousset) SAS, Rousset (FR); STMicroelectronics (Crolles 2) SAS, Crolles (FR)

(21) Appl. No.: 19/675,775

(22) Filed: May 13, 2026

Related U.S. Application Data
(62) Division of application No. 18/230,423, filed on Aug. 4, 2023.

(30) Foreign Application Priority Data
Aug. 19, 2022 (FR) FR2208404

(51) Int. Cl. H10D 64/27; H10D 30/60; H10D 64/01

(52) U.S. Cl. CPC H10D 64/518; H10D 30/601; H10D 64/01; H10D 64/516

(57) ABSTRACT

A method of forming a MOSFET transistor includes forming, on a semiconductor layer, a stack of a gate insulator and a gate region on the gate insulator. The gate region is etched to include a first gate portion and a second gate portion between the first gate portion and the gate insulator. The etching defines the first gate portion with a first length in a first lateral direction of the transistor, and defines the second gate portion with a second length in the first lateral direction that is shorter than the first length.

### CROSS REFERENCE TO RELATED APPLICATIONS

This application is a divisional of United States Application for Patent No. 18/230,423, filed August 4, 2023, which claims the priority benefit of French Application for Patent No. FR2208404, filed on August 19, 2022, the contents of which are hereby incorporated by reference in their entireties to the maximum extent allowable by law.

### TECHNICAL FIELD

The present disclosure generally concerns electronic components and more particularly Metal Oxide Semiconductor Field Effect Transistor (MOSFET) type field-effect transistors.

### BACKGROUND

MOSFET-type transistors are field-effect transistors comprising a conductive gate, for example metallic, electrically insulated from a semiconductor substrate by a dielectric layer referred to as a gate insulator.

Various embodiments of MOSFET transistors are known to those skilled in the art.

It would be desirable to at least partly overcome certain disadvantages of known embodiments of MOSFET transistors.

There is a need, in particular, for improvement in the electric performance of MOSFET transistors intended for radio frequency (RF) signal switching applications, also referred to as RF switches, for example for frequencies in the range from 400 MHz to 20 GHz.

### SUMMARY

An embodiment overcomes all or part of the disadvantages of known MOSFET transistors.

An embodiment provides a transistor comprising, on a semiconductor layer, a stack of a gate insulator and of a gate region on the gate insulator, wherein the gate region comprises a first portion and a second portion between the first portion and the gate insulator, the first portion has a first length in a first lateral direction of the transistor, and the second portion has a second length in the first direction shorter than the first length.

According to an embodiment, the transistor further comprises: a source region and a drain region in a body region of the semiconductor layer, an upper portion of the body region, between the source region and the drain region, forming a channel region of the transistor; the first direction being parallel to the length direction of the channel region, between the source region and the drain region; and the gate region topping the body region, for example, topping the channel region.

According to an embodiment, the transistor further comprises a lightly-doped drain region between the channel region and each source and drain region.

According to an embodiment, the second portion is centered in the first direction with respect to the first portion.

According to an embodiment, the thickness of the gate insulator is variable in the first direction, the gate insulator comprising a first region having a first thickness in front of a central area of the gate region, and a second region having a second thickness, greater than the first thickness, in front of the lateral edges of the second portion of the gate region.

According to an embodiment, the transistor comprises an oxide layer coating at least the sides of the gate region and, for example, an insulating spacer against the oxide layer.

According to an embodiment, the oxide layer: comprises, for example, consists of, a layer of reoxidation of the gate region, for example of thermal reoxidation; has a thickness greater than or equal to 5 nm; and/or is also positioned on, for example, covers, the first portion of the gate region.

According to an embodiment, the cavity located between the semiconductor layer and the first portion of the gate region contains a material of low dielectric constant.

According to an embodiment, the second portion of the gate region comprises, for example is made of, a polycrystalline silicon-germanium alloy, the first portion being for example made of polysilicon.

According to an embodiment, the distance, in the first direction, between the lateral edges of the first portion and of the second portion is in the range from 1 to 30 nm, for example, from 1 to 20 nm, or even from 1 to 10 nm.

An embodiment provides an electronic device comprising at least one transistor according to an embodiment.

An embodiment provides a radio frequency switch comprising at least one transistor according to an embodiment.

An embodiment provides a method of manufacturing a transistor, the method comprising the forming of a gate region on a semiconductor layer coated with a gate insulator layer, said forming comprising: a step of forming of a conductive gate layer on the gate insulator layer; a first anisotropic etching step, configured for etching the conductive gate layer preferably along a direction perpendicular to the plane of the semiconductor layer, down to a depth smaller than the thickness of said conductive gate layer, to form a first portion of the gate region having a first length in a first lateral direction of the transistor; then a second etching step, less anisotropic than the first etching step, configured for etching the conductive gate layer along the perpendicular direction all the way to the gate insulator layer and along the first direction, to form a second portion of the gate region having a second length in the first direction shorter than the first length.

According to an embodiment, the forming of the gate region further comprises, after the second etching step, a third etching step configured for etching the gate insulator layer preferably along the perpendicular direction.

According to an embodiment, the method further comprises, after the forming of the gate region: a step of deposition of a layer of a material of low dielectric constant on the semiconductor layer, preferably all the way to the level of the first portion of the gate region; then a step of etching of a portion of the layer of material non-covered with the first portion of the gate region; to fill the cavity located between the semiconductor layer and the first portion of the gate region of the material of low dielectric constant.

According to an embodiment, the forming of the gate region further comprises, after the second etching step, the forming of an oxide layer at least against the sides of said gate region, for example, by a technique of thermal reoxidation of the gate region.

According to an embodiment, the gate insulator layer has a first thickness and the forming of the gate region further comprises, after the second etching step, a step of thermal oxidation of the gate insulator layer so that said gate insulator layer reaches a second thickness greater than the first thickness in front of the edges of the second portion of the gate region and keeps substantially the first thickness in front of a central area of said gate region.

According to an embodiment: the step of forming of the conductive gate layer comprises the forming of a layer of a polycrystalline silicon-germanium alloy on a polysilicon layer; the first etching step is configured for etching the polysilicon layer; and the second etching step is configured for etching the layer made of the polycrystalline silicon-germanium alloy.

According to an embodiment, a method of manufacturing a transistor supported by a semiconductor layer comprises: coating the semiconductor layer with a gate insulator layer; forming a layer of polycrystalline silicon-germanium alloy on the gate insulator layer; forming a layer of polycrystalline silicon on the layer of polycrystalline silicon-germanium alloy; performing an anisotropic first etching step to etch the layer of polycrystalline silicon to define an upper portion of a gate region, said upper portion having a first gate length in a first lateral direction of the transistor; performing an anisotropic second etching step to etch the layer of silicon-germanium alloy to define a lower portion of the gate region, said lower portion having a second gate length in the first lateral direction of the transistor that is less than the first gate length; wherein the anisotropic second etching step is less anisotropic than the anisotropic first etching step; and forming an insulating structure on side walls of the upper and lower portions of the gate region.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A shows, in a cross-section view, an example of an electronic device comprising a MOSFET transistor;

FIG. 1B shows, in a cross-section view, another example of an electronic device comprising a MOSFET transistor;

FIG. 2 shows, in a cross-section view, an electronic device comprising a MOSFET transistor according to an embodiment;

FIGS. 3A to 3F are cross-section views partially and schematically illustrating successive steps of an example of a method of manufacturing a MOSFET transistor according to the embodiment of FIG. 2;

FIG. 4 shows, in a cross-section view, an electronic device comprising a MOSFET transistor according to another embodiment; and

FIG. 5 shows, in a cross-section view, an electronic device comprising a MOSFET transistor according to another embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, not all the steps of the MOSFET transistor manufacturing method have been described, being implementable with usual methods of microelectronics. Similarly, not all the details of the MOSFET transistors have been described. Further, the various possible applications of the described transistors have not all been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms "front", "rear", "top", "bottom", "left", "right", etc., or relative positions, such as terms "above", "under", "upper", "lower", etc., or to terms qualifying directions, such as terms "horizontal", "vertical", etc., it is referred unless specified otherwise to the orientation of the drawings or to a MOSFET transistor in a normal position of use.

In the following description, a length corresponds to a dimension in a first lateral direction of a MOSFET transistor, which corresponds to the X direction observed in the drawings, corresponding to a direction parallel to the transistor conduction direction, a thickness or a depth corresponds to a dimension in the vertical direction Z (perpendicular direction) observed in the drawings, and a width corresponds to a dimension in a second lateral direction Y, orthogonal to the X direction. Thus, the channel length of the transistor corresponds to the dimension, along the X direction, of a channel-forming region of the transistor, substantially corresponding to the distance between a source region and a drain region of the transistor.

In the following description, for convenience, a MOSFET transistor can be designated as a MOS transistor, or a transistor.

The transistors shown in the following description are, for example, N-channel MOS transistors (NMOS), that is, transistors having their source and drain regions N-type doped, for example, doped with arsenic or phosphorus atoms, while the body region is P-type doped, for example, doped with boron atoms.

As a variant, the shown transistors may be P-channel MOS transistors (PMOS), that is, transistors having their source and drain regions P-type doped, for example, doped with boron atoms, while the body region is N-type doped, for example, doped with arsenic or phosphorus atoms.

Unless specified otherwise, the expressions "around", "approximately", "substantially" and "in the order of" signify within 10%, and preferably within 5%.

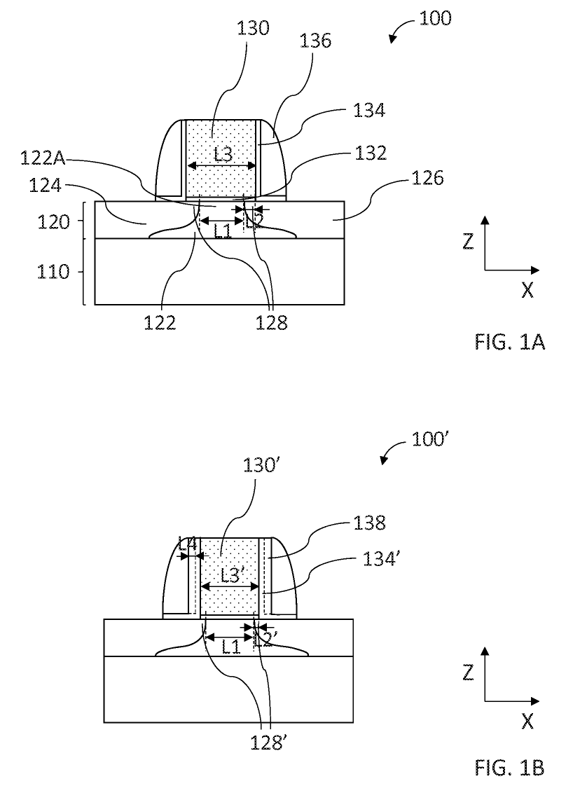

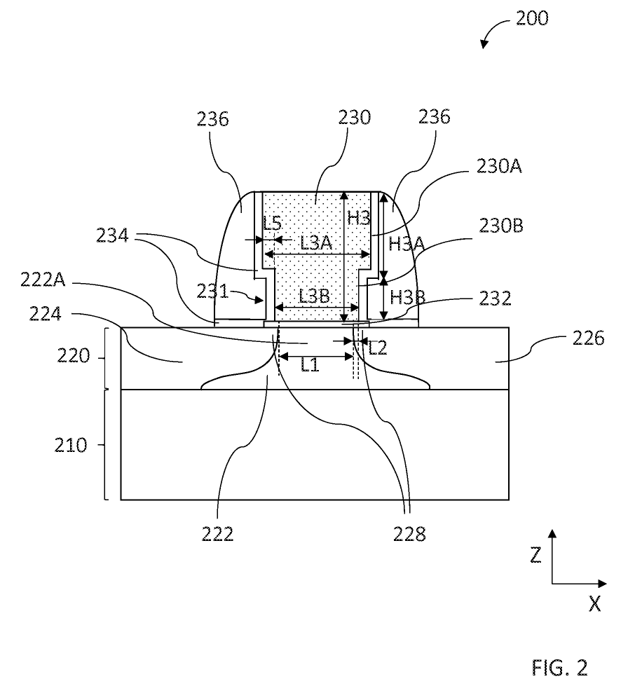

FIG. 1A shows an example of an electronic device comprising a MOSFET transistor 100 formed inside and on top of a semiconductor layer 120. The device comprises a buried insulating layer 110, under semiconductor layer 120. Layers 110 and 120 correspond, for example, to a stack of Semiconductor On Insulator (SOI) type, the device then comprising a substrate in contact with and under buried insulating layer 110 (this substrate not shown in the drawings). Semiconductor layer 120 is, for example, on top of and in contact with buried insulating layer 110.

Semiconductor layer 120 is, for example, made of silicon, for example, of single-crystal silicon, and buried insulating layer 110 is, for example, made of silicon dioxide (SiO₂).

Transistor 100 comprises a source region 124 and a drain region 126 formed in a region of semiconductor layer 120 referred to as a body region 122.

An upper portion 122A of body region 122, between source region 124 and drain region 126, forms the channel-forming region of transistor 100, or "channel region". Channel region 122A has a length L1 (in the first lateral direction X). As an example, the source 124, drain 126, and body 122 regions are flush with the upper surface of semiconductor layer 120.

Transistor 110 further comprises a gate region 130 located above body region 122. Gate region 130 is, for example, made of polysilicon. Gate region 130 may have a length L3 in the range from 50 nm to 300 nm, for example in the range from 100 nm to 200 nm.

Gate region 130 is separated from body region 122 by an insulating layer 132, referred to as the gate insulator layer, or gate insulator. As an example, the gate insulator is made of silicon dioxide (SiO₂) and has, for example, a thickness in the range from approximately 1 nm to 10 nm.

As an example, in FIG. 1A, gate insulator layer 132 is on top of and in contact with semiconductor layer 120 and gate region 130 is on top of and in contact with gate insulator layer 132.

On either side of gate region 130, on portions of semiconductor layer 120 not covered with said gate region, and on the lateral walls (sides) of gate region 130, transistor 100 comprises a thin protection oxide layer 134, for example, a SiO₂ layer.

Further, transistor 100 comprises an insulating spacer 136 which coats the sides of gate region 130 covered with oxide layer 134 and which extends on the portions of semiconductor layer 120 covered with oxide layer 134. Insulating spacer 136 is made, for example, of a silicon nitride (SiN).

In certain MOS transistors, there is formed a lightly-doped drain region (LDD) 128 between channel region 122A and each source 124/drain 126 region, by doping, generally by ion implantation, semiconductor layer 120 from the upper surface thereof. This LDD region 128 is formed after gate region 130, and generally after the forming of oxide layer 134. Thus, gate region 130, with generally oxide layer 134 on the sides of the gate region, is used as a protection mask during the operation of doping of the semiconductor layer to form LDD region 128. The LDD region enables to decrease the depth of the implanted area to limit parasitic electrostatic coupling effects between the source region and the drain region.

However, the doping operation to form these LDD regions often causes a significant overlapping of these LDD regions under gate region 130. Indeed, during the doping operation, the dopant may diffuse over a certain length under the gate region. This overlap is represented by length L2 in FIG. 1A. This forms an overlap capacitance Cov, which thereby increases the parasitic capacitance Coff, in the off state, of the transistor, which may cause a performance decrease of the transistor, for example, a switch transistor, and thus, for example, a decrease of the function of insulation of radio frequency antennas comprising such switch transistors.

To decrease the overlap, and thus decrease overlap capacitance Cov, as illustrated in FIG. 1B, a technique forms an offset spacer 138 on the lateral walls of gate region 130’ and on thin protection oxide layer 134’. The offset L4 formed by offset spacer 138 is, for example, in the range from 3 to 20 nm.

Thus, it can be seen that overlap length L2’ is decreased with respect to the overlap length L2 of FIG. 1A. Overlap length L2’ however keeps a minimum value to avoid jeopardizing the gate control along the entire length of channel L1 in case of a loss of overlap, and to avoid increasing the resistance at the level of the overlap, so as to avoid increasing the resistance Ron of the transistor.

Offset spacer 138 is formed after the forming of gate region 130’ and before the forming of LDD region 128’. Thus, offset spacer 138 forms a protection mask which continues the mask formed by the gate region for the doping operation. This enables for the dopant to diffuse over a shorter length under the gate region, and thus this enables to decrease the overlap.

If it is desired to keep substantially the same channel length L1, it may be provided to form a gate region 130’ of length L3’ decreased by approximately twice offset value L4. Since voltage RF Vmax, which is the maximum voltage that can be applied to a transistor, for example for a RF switch, without risking degrading it, increases with the channel length, it may also be chosen to increase the channel length.

Thus, an offset spacer enables to decrease product Coff*Ron and this, without decreasing voltage RF Vmax.

The offset spacer is generally formed by a layer deposition method, after the forming of gate region 130’ and of thin oxide layer 134’, for example a chemical vapor deposition (CVD) method with, as precursor, tetraethylorthosilicate (TEOS) to form a SiO₂ layer. Then, portions of the SiO₂ layer are etched to mainly keep the deposited SiO₂ on the sides of gate region 130’, which forms offset spacer 138. These operations generally require forming an etch mask, and then the removal of this mask.

Thus, a disadvantage of this fabrication technique is that this adds steps necessary to the forming of an offset spacer in the manufacturing method of the transistor, and thus of the electronic device.

The inventors provide a MOSFET transistor enabling to address the previously-described improvement needs, and to overcome all or part of the disadvantages of the previously-described transistors. In particular, the inventors provide a MOSFET transistor which enables to improve the tradeoff between the Coff*Ron, which is desired to be minimized, and voltage RF Vmax, which is desired to be maximized, and this, without complicating the transistor manufacturing method, in particular without adding time-consuming and expensive steps.

Embodiments of MOSFET transistors will be described hereafter. The described embodiments are non-limiting and various variants will occur to those skilled in the art based on the indications of the present disclosure.

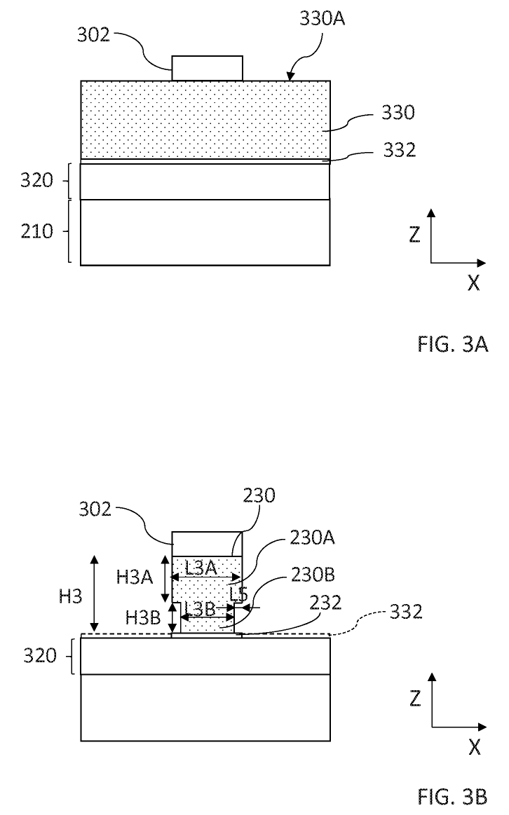

FIG. 2 shows, in a cross-section view, an electronic device comprising a MOSFET transistor 200 according to an embodiment.

Similarly to the transistor 100 of FIG. 1A, MOSFET transistor 200 is formed inside and on top of a semiconductor layer 220. The device comprises a buried insulating layer 210, under semiconductor layer 220. Layers 210 and 220 correspond, for example, to an SOI-type stack, the device then comprising a substrate in contact with and under buried insulating layer 210 (this substrate not shown in the figures). Semiconductor layer 220 is, for example, on top of and in contact with buried insulating layer 210.

Semiconductor layer 220 is, for example, made of silicon, for example, of single-crystal silicon. Semiconductor layer 220 may have a thickness in the range from 10 nm to 500 nm, for example, from 50 nm to 200 nm, for example, in the order of 60 nm or in the order of 160 nm.

As an example, buried insulating layer 210 is made of silicon dioxide (SiO₂). Buried insulating layer 210 may have a thickness in the range from 100 nm to 600 nm, for example, from 200 nm to 450 nm, for example, in the order of 400 nm.

Transistor 200 comprises a source region 224 and a drain region 226 formed in a region of semiconductor layer 220, referred to as a body region 222.

An upper portion 222A of body region 222, between source region 224 and drain region 226, forms the channel region of transistor 200. Channel region 222A has a length L1.

A lightly-doped drain region (LDD) 228 is formed between channel region 222A and each source 224/drain 226 region.

As an example, the source 224, drain 226, and body 222 regions are flush with the upper surface of semiconductor layer 220.

Transistor 210 further comprises a gate region 230 located above body region 222, for example, above channel region 222A.

Transistor 200 differs from the transistor 100 of FIG. 1A mainly in that gate region 230 comprises an upper portion 230A (first portion) and a lower portion 230B (second portion). Upper portion 230A has a length L3A (first length) greater than the length L3B (second length) of lower portion 230B, so that the upper portion further extends on either side above the lower portion. The lower portion is, for example, centered in the X direction with respect to the upper portion, but this is not limiting.

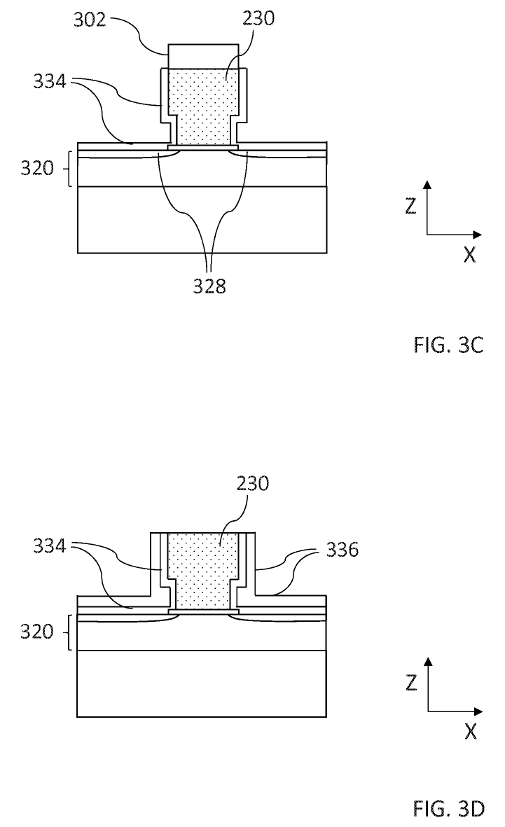

Gate region 230 thus has a shape with a notch 231 in its lower portion. The length L5 of notch 231 substantially corresponds to half the difference between L3A and L3B, and may vary for example between 5 and 25 nm, or even between 5 and 15 nm. This value may be controlled, as explained in the example of manufacturing method described in relation with FIGS. 3A to 3F.

The lower portion 230B of gate region 230 enables to decrease the overlap between LDD region 228 and gate region 230, thus enabling to decrease overlap capacitance Cov, while the upper portion 230A of gate region 230 forms a protection mask during the operation of doping of semiconductor layer 220 to form LDD region 228, and this protection mask may be sized to decrease the dopant diffusion during this doping operation. Further, this enables to limit the number of operations of the method, as compared with the transistor 100’ of FIG. 1B, the shape of the gate region being obtained by controlling the etching of the gate region, without necessarily adding steps, such as those necessary to the forming of an offset spacer. This is illustrated in the example of manufacturing method of FIGS. 3A to 3F.

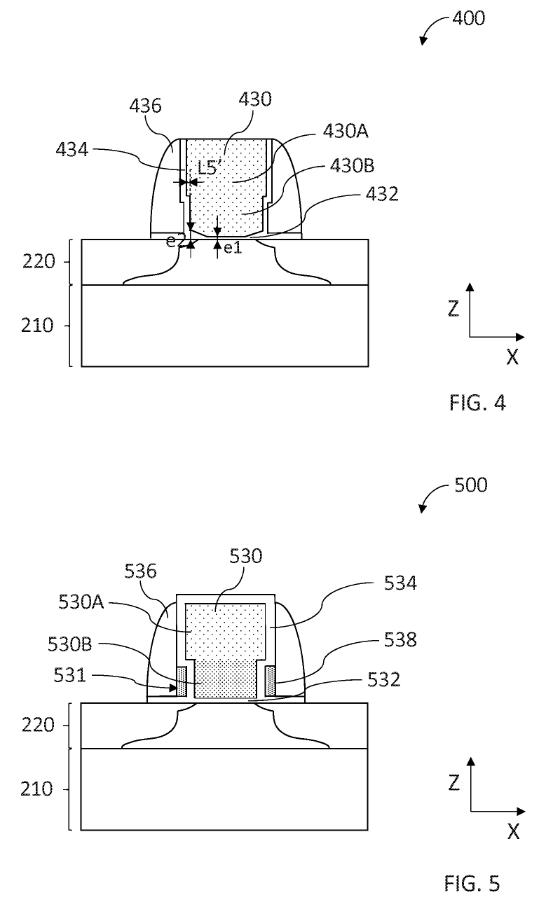

According to an example, the first and second portions of the gate region 230 are made of polysilicon, but this is not limiting, as for example described in relation with FIG. 5.

The height H3A (first height) of upper portion 230A and the height H3B (second height) of lower portion 230B may vary. For example, increasing H3B enables to further decrease overlap capacitance Cov.

For example, gate region 230 has: a first length L3A in the range from 60 to 500 nm, for example in the range from 80 to 200 nm; a second length L3B in the range from 30 to 490 nm or from 50 to 470 nm, for example in the range from 50 to 190 nm or from 70 to 170 nm, or even from 50 to 80 nm; a total height H3 in the range from 50 to 140 nm, for example, in the range from 70 to 110 nm; a first height H3A in the range from 40 to 90 nm, for example, in the range from 60 to 80 nm; a second height H3B in the range from 10 to 50 nm, for example in the range from 10 to 30 nm.

Gate region 230 is separated from body region 222 by an insulating layer 232 (gate insulator). As an example, the gate insulator is made of silicon dioxide (SiO₂).

The gate insulator has, for example, a thickness in the range from approximately 1 nm to 10 nm. The gate insulator may have a thickness in the range form approximately 1 to 4.5 nm, for example approximately 2.1 nm, for a transistor referred to as GO1 ("Gate Oxide 1"), that is, a transistor with a gate insulator of relatively speaking a lower thickness, or a thickness in the range from approximately 5 to 7.5 nm, for example, approximately 6.5 nm, for a transistor referred to as GO2 ("Gate Oxide 2"), that is, a transistor with a gate insulator of relatively larger thickness.

As an example, in FIG. 2, gate insulator layer 232 is on top of and in contact with semiconductor layer 220 and the lower portion 230B of gate region 230 is on top of and in contact with gate insulator layer 232.

On either side of gate region 230, on portions of semiconductor layer 220 not covered with the lower portion 230B of the gate region, and on the sides of gate region 230, transistor 200 comprises a thin protective oxide layer 234, for example, a SiO₂ layer. The thickness of the thin oxide layer is, for example, in the range from 2 to 10 nm, or even from 2 to 5 nm. On the sides of gate region 230, the thin protective oxide layer 234 takes the shape of said gate region.

Further, transistor 200 comprises an insulating spacer 236 which coats the sides of the gate region 230 covered with oxide layer 234 and which extends on the portions of semiconductor layer 220 covered with oxide layer 234. Insulating spacers 236 is, for example, made of a silicon nitride (SiN).

FIGS. 3A to 3F are cross-section views partially and schematically illustrating successive steps of an example of a method of manufacturing a MOSFET transistor 200 according to the embodiment of FIG. 2.

FIG. 3A shows an initial structure comprising a buried insulating layer 210, topped with a semiconductor layer 320. The structure of FIG. 3A further comprises a gate insulator layer 332 on semiconductor layer 320, and a conductive gate layer 330 on gate insulator layer 332.

Conductive gate layer 330 is topped with a masking layer 302. Masking layer 302 partially covers the upper surface 330A of conductive gate layer 330 for an etching step which is detailed hereafter in relation with FIG. 3B.

FIG. 3B corresponds to a structure obtained at the end of a step of etching of the conductive gate layer 330 of the structure illustrated in FIG. 3A. During this step, conductive gate layer 330 is etched, from its upper surface 330A, so that only the portion of conductive gate layer 330 located under masking layer 302 remains, the portions of conductive gate layer 330 not covered with masking layer 302 being removed.

The etching step is performed in at least two consecutive steps: step 1) a first anisotropic etching step configured for etching conductive gate layer 330 from the upper surface 330A of said layer preferably in vertical direction Z, where this etching is performed down to a depth H3A, corresponding to the height of the upper portion 230A of future gate region 230; then step 2) a second etching step, less anisotropic (or more isotropic) than the first etching step, configured for etching the rest of conductive gate layer 330 vertically down to a depth H3B laterally along a length L5 towards the center of the future gate region, forming the lower portion 230B of gate region 230, where the length L5 defines a notch (see, also reference 531, FIG. 5) in the gate region at the lower portion.

For example, the first etching step is performed with chlorine (Cl₂) and carbon tetrafluoride (CF₄), for example for a duration in the range from 10 to 70 seconds.

For example, the second etching step is performed with hydrogen bromide (HBr), for example, for a duration in the range from 50 to 150 seconds.

Upper portion 230A has a length L3A greater than the length L3B of lower portion 230B, so that the upper portion extends on either side above the lower portion. The height H3A of upper portion 230A and the height H3B of lower portion 230B may be defined by adjusting or tuning the etching conditions and the transition between the first etching step and the second etching step. Length L5 may be modified by adjusting or tuning the conditions of the second etching step, for example to make it more or less anisotropic.

As an example, the etching method shown then comprises: step 3) a third step of etching of gate insulator layer 332 to, at the end of this etching, only leave gate insulator 232 under gate region 230. This third etching step is preferably an anisotropic etching configured for etching gate insulator layer 332 preferably in vertical direction Z.

As an example, the etching method may be configured for etching in steps 1 and 2 the material of conductive gate layer 330 selectively over the material of gate insulator layer 332. Gate insulator layer 332 may then play the role of a barrier to the etching so that the etching stops on the upper surface of gate insulator layer 332 (shown in dotted lines in FIG. 3B). According to this variant, at the end of the etching step, gate insulator layer 332 is still present, even in the portions not covered with gate region 230.

FIG. 3C corresponds to a structure obtained at the end of: a step of forming of a thin protection oxide layer 334, for example, a SiO₂ layer, on the sides of gate region 230 and on semiconductor layer 320, for example, by a CVD technique (where, on the sides of gate region 230, the thin protection oxide layer 334 takes the shape of said gate region); and a step of performing a first ion implantation to form lightly-doped drain (LDD) regions 328 in semiconductor layer 320.

The order of these two steps may be permuted.

FIG. 3D corresponds to a structure obtained at the end of: a step of removal of masking layer 302; and then a step of forming of an insulator layer 336 which coats the sides of gate region 230 covered with oxide layer 334 and which extends on the portions of semiconductor layer 320 covered with oxide layer 334.

FIG. 3E corresponds to a structure obtained at the end of a step of etching of insulator layer 336 to form insulating spacers 236 on the sides of gate region 230 covered with oxide layer 334.

FIG. 3F corresponds to a structure obtained at the end of: a step of etching of the portions of oxide layer 334 not covered with insulating spacers 236, forming thin protection oxide layer 234; and then a second step of ion implantation to form source 224 and drain 226 regions in semiconductor layer 320, forming semiconductor layer 220 with the source, drain, body, and channel regions.

For an NMOS transistor, the first and second ion implantation steps may use n-type dopants such as arsenic (As) or phosphorus (P). For a PMOS transistor, the first and second ion implantation steps may use p-type dopants such as boron (B).

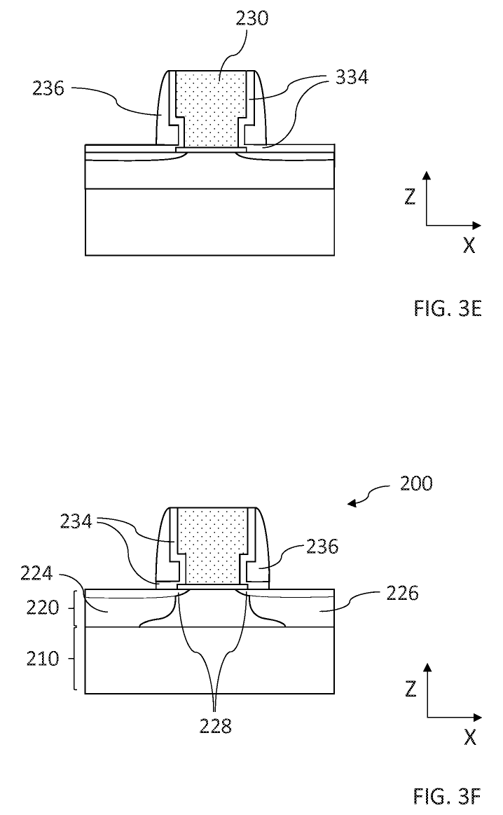

FIG. 4 shows, in a cross-section view, an electronic device comprising a MOSFET transistor 400 according to another embodiment.

Transistor 400 differs from the transistor 200 of FIG. 2 essentially in that the thickness e1 of the gate insulator 432 under a central area of gate region 430 is smaller than the thickness e2 of gate insulator 432 under peripheral areas of the gate region, for example particularly around areas where gate insulator 432 is not covered with the lower portion 430B of gate region 430.

As an example, between gate region 430 and semiconductor layer 220, gate insulator 432 has a thickness decreasing from the edges of the lower portion 430B of gate region 430 towards the center of said gate region. For example, the thickness of the gate insulator decreases in a substantially continuous fashion between thickness e2 and thickness e1, in the X direction of the channel length of the transistor from the edges of the lower portion 430B of gate region 430 to a central area of the gate region.

As an example, thickness e1 is in the range from 1 to 6 nm, or even from 2 to 3 nm, and thickness e2 is in the range from 5 to 10 nm, or even from 5 to 7 nm.

This thickness increase may be obtained by a step of thermal oxidation of gate insulator layer 432, after the etching step forming gate region 430. As an example, the thermal oxidation step is carried out at a temperature in the range from 300°C to 1,200°C, for example, in the range from 500°C to 1,000°C, for example, in the order of 900°C. As an example, the thermal oxidation step is a fast thermal oxidation, carried out for a duration in the range from 1 second (s) to 2 minutes (min), for example in the range from 20 s to 1 min, for example in the order of 35 s.

The provision of a relatively thick gate insulator 432 (thickness e2) under a peripheral area of gate region 430 enables to decrease the parasitic capacitance Coff, in the off state, of transistor 400, between semiconductor layer 220 and gate region 430. The maintaining of a relatively low thickness of gate insulator 432 (thickness e1) under a central area of gate region 430 however enables to decrease, or not to significantly increase, the on-state resistance of the transistor. A particularly advantageous decrease of product Ron*Coff can thus be obtained, particularly for RF signal switching applications.

This effect of decrease of product Ron*Coff may be particularly reinforced since the gate region of the transistor comprises a notch in its lower portion. Indeed, the oxidation, and thus the thickness increase, may be performed substantially under the notch and thus at the level of an overlap area decreased due to this gate region shape, and the combination of the decrease of the overlap length and of the gate insulator thickness increase at the level of this overlap area enables to further decrease parasitic capacitance Coff.

Further, there has been shown in FIG. 4, as an example, a notch length L5’ shorter than the notch length L5 of the transistor 200 of FIG. 2. This feature is not necessarily combined with the previously-described feature.

FIG. 5 shows, in a cross-section view, an electronic device comprising a MOSFET transistor 500 according to another embodiment.

Transistor 500 differs from the transistor 200 of FIG. 2 mainly by three features that may be considered individually or in combination.

Transistor 500 may comprise an oxide layer 534, for example made of SiO₂, thicker than the oxide layer 234 of FIG. 2, for example, greater than 5 nm.

This thicker oxide layer may be obtained by a step of reoxidation of gate region 530 (for example, by a usual thermal reoxidation technique of microelectronics), after the etching step intended to form said gate region. It can then be referred to as a "gate region reoxidation layer" or "reoxidation layer". This reoxidation step may be followed (or preceded) by a chemical vapor deposition (CVD), for example, with TEOS as a precursor.

This thicker oxide layer may enable to further decrease overlap capacitance Cov.

The cavity formed by notch 531 in the lower portion of gate region 530 may be filled with a material 538 of low dielectric constant ("low-K", for "low-K material"), that is, a material having a dielectric constant smaller than that of SiO₂, for example, a silicon oxycarbide (SiCO), or a boron-silicon carbonitride (SiBCN).

This may be obtained by a step of deposition of a low-K material on semiconductor layer 220, after the etching step intended to form said gate region, and for example after the step of forming of oxide layer 534, then by a step of etching of the layer of low-K material, the upper portion 530A of the gate region protecting the portion of low-K material arranged under it during this etching step.

The layer of low-K material preferably has a thickness at least equal to the height H3B of the lower portion 530B of gate region 530.

This layer of low-K material in notch 531 may enable to decrease the lateral capacitance of said notch, as well as overlap capacitance Cov, and thus to further decrease capacitance Coff.

The lower portion 530B of gate region 530 may be processed to comprise, for example, to be made of, a polycrystalline silicon-germanium alloy (SiGe). This may be obtained by forming a polycrystalline SiGe conductive gate layer under the polycrystalline Si conductive gate (by a standard technique of microelectronics). For example, the fist etching step is configured for (i.e., is selective to) etching the polycrystalline Si, and the second etching step is configured for (i.e., is selective to) etching the polycrystalline SiGe. The two etching steps may follow each other in a same etch platform or in different platforms (for example, the SiGe may be etched in wet phase, while the Si is dry-etched).

This feature of the gate region enables to improve the control of the etching of gate region 530 and particularly to improve the control of the forming of notch 531 between the first 530A and second 530B portions of gate region 530. This feature may also enable to decrease the depletion of the polysilicon.

The disclosed embodiments may be combined with each other. For example, one or a plurality of the features described in relation with FIG. 5 may be combined with features described in relation with FIG. 2 and/or with FIG. 4.

Further, for each described embodiment, the length L5 of the notch formed in the gate region may vary, for example, between 1 and 30 nm, preferably from 1 to 25 nm, and more preferably still between 5 and 25, or even between 5 and 15 nm.

Thus, the embodiments may enable to minimize the product Ron*Coff of a MOSFET transistor, without for this to impact other performance factors of the transistor, for example without for this to impact the maximum applicable voltage RF Vmax. Further, this effect may cumulate with other improvements to minimize product Ron*Coff and/or to maximize the RF Vmax, for example with improvements brought to the very structure of a MOSFET transistor.

The embodiments may find applications for electronic components used in RF (radio frequency) communication applications, for example, for RF signal switching technologies (RF switch) and/or radio antenna front-end modules (FEM). For RF switches, the embodiments enable in particular to decrease parasitic capacitances without degrading voltage RF Vmax and to decrease the drain leakage induced by the gate, thus enabling to improve the switch performance at lower cost, for example to reach a higher operating speed.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

1. A method of manufacturing a transistor supported by a semiconductor layer, comprising:
coating the semiconductor layer with a gate insulator layer;
forming a layer of polycrystalline silicon-germanium alloy on the gate insulator layer;
forming a layer of polycrystalline silicon on the layer of polycrystalline silicon-germanium alloy;
performing an anisotropic first etching step to etch the layer of polycrystalline silicon to define an upper portion of a gate region, said upper portion having a first gate length in a first lateral direction of the transistor;
performing an anisotropic second etching step to etch the layer of silicon-germanium alloy to define a lower portion of the gate region, said lower portion having a second gate length in the first lateral direction of the transistor that is less than the first gate length;
wherein the anisotropic second etching step is less anisotropic than the anisotropic first etching step; and
forming an insulating structure on side walls of the upper and lower portions of the gate region.

2. The method of claim 1, further comprising using the gate insulator layer as an etch stop for the anisotropic second etching step.

3. The method of claim 1, further comprising performing an anisotropic third etching step to etch the gate insulator layer for removal from an upper surface of the semiconductor layer where not covered by the lower portion of the gate region.

4. The method of claim 1, wherein forming the insulating structure comprises: depositing a layer of oxide on the side walls of the upper and lower portions of the gate region; forming an insulator layer over the layer of oxide; and etching the insulator layer to define spacers for the gate region.

5. The method of claim 4, wherein a difference between the first and second gate lengths defines a notch in the lower portion of the gate region, and wherein forming the insulating structure further comprises depositing, before forming the insulator layer over the layer of oxide, a low-k dielectric material within the notch, wherein the low-k dielectric material covers the layer of oxide in the notch.

6. The method of claim 1, wherein the gate insulator layer coating the semiconductor layer has a first thickness, the method further comprising, after performing the anisotropic second etching step and before forming the insulating structure, performing a thermal oxidation of the gate insulator layer so that said gate insulator layer has a second thickness greater than the first thickness at edges of the lower portion of the gate region and substantially retains the first thickness at a central area of the gate region.

7. The method of claim 1, wherein the anisotropic second etching step is a wet etch and the anisotropic first etching step is a dry etch.

8. The method of claim 1, wherein the anisotropic second etching step is selective as to silicon-germanium and the anisotropic first etching step is selective as to silicon.

9. The method of claim 1, further comprising:
forming a source region and a drain region in a body region of the semiconductor layer, wherein an upper portion of the body region, between the source region and the drain region, forms a channel region of the transistor;
wherein the first lateral direction is parallel to a length direction of the channel region, said length direction extending between the source region and the drain region; and
wherein the gate region extends over the channel region of the body region.

10. The method according to claim 9, further comprising forming a lightly-doped drain region between the channel region and each source and drain region.
